(19) United States
(12) Patent Application Publication
(10) Pub. No.: US 2023/0291216 A1
(43) Pub. Date: Sep. 14, 2023

(54) MONITORING BATTERY VOLTAGE DELIVERY

(71) Applicants: STMicroelectronics (Rousset) SAS, Rousset (FR); STMicroelectronics (Alps) SAS, Grenoble (FR)

(72) Inventors: Alexandre TRAMONI, Le Beausset (FR); Nicolas LAFARGUE, Biviers (FR)

(73) Assignees: STMicroelectronics (Rousset) SAS, Rousset (FR); STMicroelectronics (Alps) SAS, Grenoble (FR)

(21) Appl. No.: 18/117,619

(22) Filed: Mar. 6, 2023

(30) Foreign Application Priority Data
Mar. 8, 2022 (FR) 2202016

(51) Int. Cl. H02J 7/00; G06F 1/28; H04B 5/00

(52) U.S. Cl. CPC H02J 7/0047; H02J 7/00711; H02J 7/007182; G06F 1/28; H04B 5/0043

(57) ABSTRACT

A circuit monitors a first voltage delivered by a battery. The monitored first voltage is compared with a second voltage. When the comparator detects that the first voltage is smaller than the second voltage, a counter starts counting. If the value of the counter during said counting exceeds a limiting value, an interruption signal is generated to control an operating mode of an electronic device power by said battery.

### PRIORITY CLAIM

This application claims the priority benefit of French Application for Patent No. 2202016, filed on Mar. 8, 2022, the content of which is hereby incorporated by reference in its entirety to the maximum extent allowable by law.

### TECHNICAL FIELD

The present disclosure generally concerns electronic systems and devices powered by a battery. More particularly, the present disclosure concerns the monitoring of the voltage delivered by a battery.

### BACKGROUND

A great number of currently used electronic systems and devices comprise an internal battery at least partially powering them.

Generally, it is expected from a battery to deliver a DC voltage. However, most batteries exhibit voltage drops capable of preventing the proper operation of the electronic system or device.

It would be desirable to be able to at least partly improve the powering of an electronic system or device by a battery.

There is a need for a higher-performance powering by a battery of an electronic system or device.

There is a need to detect a voltage drop of a battery of an electronic system or device.

There is a need to prevent an electronic system or device from a voltage drop of its battery.

There is a need to overcome all or part of the disadvantages of known battery power supplies.

### SUMMARY

An embodiment provides a circuit for monitoring a first voltage delivered by a battery, comprising: a comparator configured to compare the first voltage with a second voltage; and a counter configured to start counting each time the comparator indicates that the first voltage is smaller than the second voltage, wherein an interruption signal is generated if a value of the counter during said counting exceeds a limiting value.

Another embodiment provides a method of monitoring a first voltage delivered by a battery carried out by a monitoring circuit, comprising: comparing the first voltage with a second voltage; starting a counting each time the first voltage is smaller than the second voltage; and generating an interruption signal when the value of the counter during said counting exceeds a limiting value.

According to an embodiment, the monitoring circuit further comprises a circuit configured to generate an interruption signal when the comparator indicates that the first voltage is greater than the second voltage.

According to an embodiment, the interruption signal is configured to modify the operating mode of the electronic device comprising said battery.

According to an embodiment, if the interruption signal is generated because said value of the counter exceeds the limiting value then said electronic device switches to a low-consumption mode.

According to an embodiment, if the device is in a low-consumption mode, the interruption signal generated because the value of said counter is greater than said limiting value is disabled.

According to an embodiment, said device comprises a processor having, during a low-consumption mode, a decreased clock frequency.

According to an embodiment, if the interruption signal is generated because said first voltage is greater than the second voltage, then said electronic device switches to a full power mode.

According to an embodiment, if the device is in a full power mode, the interruption signal generated because said first voltage is greater than said second voltage is disabled.

According to an embodiment, the counter is configured to reset to zero each time the first voltage is greater than the second voltage. According to an embodiment, the counter is configured to reset to zero each time said value of the counter is greater than said limiting value.

According to an embodiment, the second voltage is configurable.

According to an embodiment, the limiting value is configurable.

In an embodiment, an electronic device comprises a battery and a monitoring circuit as previously-described.

According to an embodiment, the device further comprises a near-field communication circuit.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 very schematically shows in the form of blocks an electronic device capable of comprising an embodiment of FIGS. 3 to 5;

FIGS. 2A-2B show graphs illustrating a voltage delivered by a battery;

FIG. 3 shows a simplified embodiment of a circuit for monitoring a voltage delivered by a battery;

FIG. 4 shows another more detailed embodiment of a circuit for monitoring a voltage delivered by a battery; and

FIG. 5 shows timing diagrams illustrating the operation of the embodiments of FIGS. 3 and 4.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

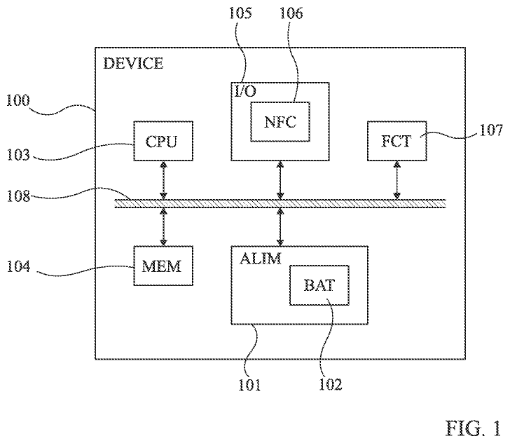

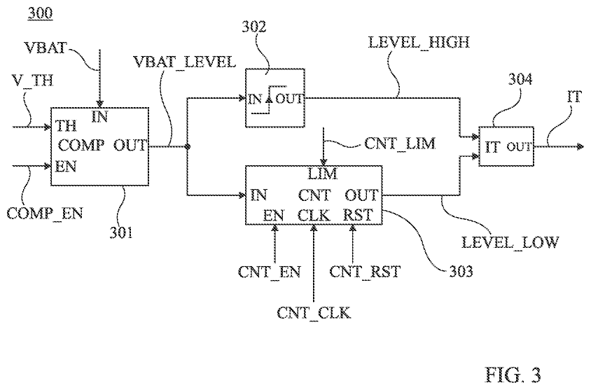

FIG. 1 very schematically shows in the form of blocks an example of an electronic device 100 (DEVICE) capable of comprising an embodiment of a battery monitoring circuit described in relation with FIGS. 3 to 5.

Device 100 is an electronic device, such as a cell phone, a connected device, having its energy supply delivered at least partially internally. Thus, device 100 comprises an internal energy supply system 101 (ALIM) comprising at least one battery 102 (BAT). Energy supply system 101 further comprises circuits enabling to manage the energy supply of device 100.

Device 100 further comprises circuits and electronic components enabling it to implement at least one, preferably a plurality of, functionalities. These circuits and components are described as an indication and are not limiting. It will be within the abilities of those skilled in the art to determine which circuit or component are essential to device 100 according to the functionalities that it implements. More particularly, device 100 may comprise: a processor 103 (CPU); one or a plurality of memories 104 (MEM); one or a plurality of internal and/or external communication circuits 105 (I/O) comprising, for example, a near-field communication module 106 (NFC); various circuits 107 (FCT) enabling it to implement various functionalities; and one or a plurality of bus interfaces 108 enabling the different circuits and components to exchange data and/or energy.

Circuits 107 may comprise one or a plurality of data measurement or processing circuits, one or a plurality of secure elements, that is, reliable electronic devices enabling to process critical or secret data, one or a plurality of display devices, etc.

In FIG. 1, a single bus 108 is shown and couples all the circuits and components of device 100 together, but a plurality of buses 108 coupling certain circuits and components together may be envisaged.

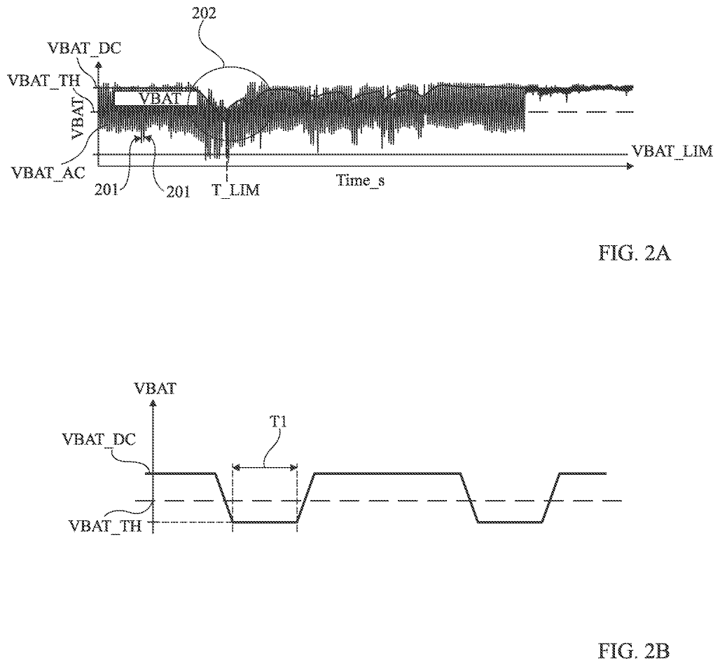

FIGS. 2A-2B show graphs illustrating the voltage delivered by a battery of the type of the battery 102 of the device 100 described in relation with FIG. 1. More particularly, FIG. 2A represents a real time measurement of a voltage VBAT delivered by a battery, and FIG. 2B represents a simplified version of a time variation of voltage VBAT.

The battery in question herein is supposed to deliver a DC voltage, however the voltage VBAT delivered by the battery comprises a DC component VBAT_DC and an AC component VBAT_AC, visible in graph (A).

AC component VBAT_AC comprises a multitude of voltage drops 201, or negative peaks. These voltage peaks may in general neither be anticipated, nor be avoided.

DC component VBAT_DC may also comprise voltage drops 202 which differ from voltage drops 201 in that voltage drops 202 have a longer duration than voltage drops 201.

A problem that may occur is that when DC and AC components VBAT_DC and VBAT_AC exhibit voltage drops at the same time, like at time T LEVI visible in graph (A), voltage VBAT may become smaller than a limiting voltage VBAT_LIM and may disturb the operation of the device which is powered by the battery.

In graph (B), there is defined a way to detect a voltage drop 202 of the DC component VBAT_DC. It is considered that component VBAT_DC exhibits a voltage drop 202 when during a voltage drop having a minimum duration T1, voltage VBAT is smaller than a threshold voltage VBAT_TH, greater than limiting voltage VBAT_LIM. According to an example, minimum duration T1 is in the order of 4 ms.

The embodiments described in relation with FIGS. 3 to 5 aim at preventing the device from a voltage drop of the type of voltage drop 202 as defined in relation with graph (B) so that it can act accordingly.

FIG. 3 very schematically illustrates in the form of blocks an embodiment of a circuit 300 for monitoring a voltage delivered by a battery. Circuit 300 may form part of the power supply system 101 of device 100 described in relation with FIG. 1 and enables to prevent device 100 from the occurrence of voltage drops of the type of the voltage drops 202 described in relation with FIG. 1 occurring on the voltage delivered by battery 102.

Monitoring circuit 300 comprises: a comparator 301 (COMP); an edge detector 302; a counter 303 (CNT); and an interruption generator 304 (IT).

Comparator 301 comprises at least three inputs IN, TH, and EN, and at least one output OUT. Input IN receives the voltage to be compared, here a voltage VBAT delivered by a battery. Input TH receives the threshold voltage with respect to which the voltage received on input IN is compared, here input TH receives a threshold voltage V_TH, defined in the same way as the voltage VBAT_TH described in relation with FIG. 3. Input EN receives a voltage for enabling comparator 301, here, input EN receives a voltage COMP_EN. Output OUT delivers a comparison voltage VBAT LEVEL obtained by comparison of voltage VBAT with threshold voltage V_TH. According to an example, voltage VBAT LEVEL is at a first level, for example, a high level, when voltage VBAT is greater than threshold voltage V_TH, and at a second level, for example, a low level, when voltage VBAT is smaller than threshold voltage V_TH.

Edge detector 302 comprises at least one input IN and at least one output OUT. Input IN receives comparison voltage VBAT LEVEL, and output OUT delivers an edge detection voltage LEVEL_HIGH. Edge detector 302 is configured to indicate to the device that voltage VBAT is greater than threshold voltage V_TH by detecting a transition edge from the second level to the first level of comparison voltage VBAT LEVEL. In other words, each time voltage VBAT LEVEL indicates that voltage VBAT is greater than threshold voltage V_TH, the output voltage LEVEL_HIGH of detector 302 indicates it, for example, by switching to a third level, for example, a high level.

According to a practical example, if comparison voltage VBAT LEVEL is at a high level when voltage VBAT is greater than threshold voltage V_TH, then detector 302 is a rising edge detector. In the opposite case, detector 302 is a falling edge detector. Those skilled in the art will be able to adapt the rest of circuit 300 according to these two alternatives.

Counter 303 (CNT) comprises at least five inputs IN, EN, CLK, RST, and LIM, and at least one output OUT. Input IN receives comparison voltage VBAT LEVEL. Input EN receives a voltage for enabling counter 302, here input EN receives a voltage CNT_EN. Input CLK receives a clock signal of counter 302, here input CLK receives a signal CNT_CLK. Input RST receives a voltage for resetting counter 302 enabling to reset counter 302 to its initial value, here input RST receives a voltage CNT_RST. According to an example, voltage CNT_RST is dependent on voltage LEVEL_HIGH. Input LIM receives the voltage CNT_LIM for programming a limiting value with which the value of the counter is compared. This limiting value is decided so that the counting of the counter from its initial value to the limiting value takes a time in the order of the duration T1 defined in relation with FIGS. 2A-2B. Output OUT delivers an output voltage LEVEL_LOW indicating whether the value of counter 303 has exceeded limiting value CNT_LIM.

Interruption generation 304 comprises at least two inputs and one output OUT. Generator 304 receives at its input voltages LEVEL_HIGH and LEVEL_LOW and outputs an interruption signal IT. Generator 304 takes into account the information of voltages LEVEL_HIGH and LEVEL_LOW to generate an interruption indicating to the device that the voltage VBAT delivered by the battery exhibits a voltage drop having an extended duration, or has become greater than threshold voltage V_TH.

Circuit 300 operates as follows. Comparator circuit 301 continuously compares voltage VBAT and threshold voltage V_TH to deliver voltage VBAT LEVEL. Two cases may occur.

First case: voltage VBAT is smaller than threshold voltage V_TH. Comparison voltage VBAT LEVEL indicates this information by being at the second level, for example, the low level. From the time when voltage VBAT has become smaller than threshold voltage V_TH, counter 303 has been started.

If the value of the counter reaches limiting value CNT_LIM without having the state of voltage VBAT LEVEL to vary, it is considered that the voltage drop of voltage VBAT has lasted too long and the device powered by the battery delivering voltage VBAT has to be warned. In this case, an interruption signal has to be sent. Counter 303 is then reset to zero. However, if the counter value is reset to zero, for example because voltage VBAT LEVEL exhibits a new edge, no interruption signal is sent.

This interruption signal may have different consequences. It enables to inform the device that the battery performance is insufficient for its proper operation. According to an embodiment, on reception of this interruption signal, the device may decide to switch to a “low consumption” or “low power” mode, that is, a mode where the device decreases its energy consumption. According to a preferred embodiment, during a “low consumption” mode, the device may decrease the operating frequency of its processor.

Second case: voltage VBAT is greater than threshold voltage V_TH. At the time when voltage VBAT has becomes greater than threshold voltage V_TH, detector 302 informs generator 304, which generates an interruption signal.

This interruption signal may have different consequences. It enables to inform the device that the battery performance has become sufficient again to have it properly operate. According to an embodiment, on reception of this interruption signal, the device may decide to switch back to a normal consumption mode, that is, a mode where the device does not decrease its energy consumption. The interruption signal further aims at resetting the counter to its initial value.

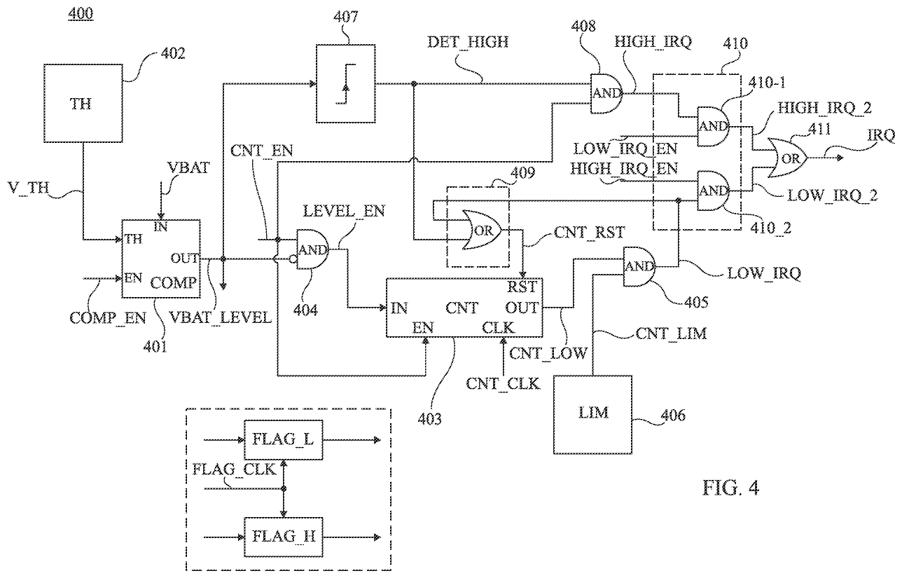

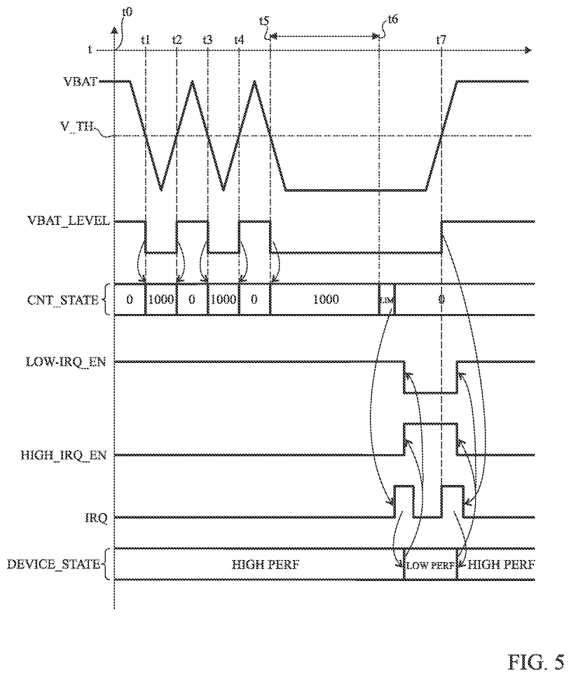

The monitoring circuit and its operation are described in further detail in relation with FIGS. 4 and 5.

FIG. 4 partially shows in the form of blocks a more detailed embodiment of a circuit 400 for monitoring a voltage delivered by a battery of the type of the monitoring circuit 300 described in relation with FIG. 3.

Like circuit 300, circuit 400 is configured to being included in a system for powering an electronic device D of the type of the device 100 described in relation with FIG. 1. Thus, the battery having circuit 400 associated therewith is of the type of battery 102 and circuit 400 forms part of power supply circuits 101.

Circuit 400 comprises a comparator 401 (COMP) of the type of the comparator 301 described in relation with FIG. 3. Thus, comparator 401 comprises at least three inputs IN, TH, and EN, and at least one output OUT. Input IN receives the voltage to be compared, here the voltage VBAT delivered by the battery of device D. Input TH receives the threshold voltage with respect to which the voltage received on input IN is compared, here input TH receives a threshold voltage V_TH. Input EN receives a voltage for enabling comparator 401, here input EN receives a voltage COMP_EN. Output OUT delivers a comparison voltage VBAT LEVEL obtained by comparison of voltage VBAT with threshold voltage V_TH. In the example of circuit 400, voltage VBAT LEVEL is at a high level when voltage VBAT is greater than threshold voltage V_TH, and at a low level when voltage VBAT is smaller than threshold voltage V_TH. Those skilled in the art will be capable of adapting circuit 400 in the opposite case.

Circuit 400 further optionally comprises circuit 402 (TH) for generating the voltage providing threshold voltage V_TH. Circuit 402 may be a configurable voltage source driven by a control unit of device D. According to a variant, circuit 402 may be a simple voltage source. According to another variant, circuit 402 may be external to circuit 400, and/or external to device D.

Circuit 400 further comprises a counter 403 (CNT) associated with a first “AND”-type logic gate 404 and a second “AND”-type logic gate 405.

Counter 403 (CNT) comprises at least four inputs IN, CLK, EN, and RST, and at least one output OUT. Input IN receives a voltage LEVEL_EN delivered by the output of gate 404 described in further detail hereafter. Input CLK receives a clock signal of counter 403, here input CLK receives a signal CNT_CLK. Input EN receives a voltage for enabling counter 403, here input EN receives a voltage CNT_EN. Input RST receives a voltage for resetting counter 403 enabling to reset counter 403 to its initial value, here input RST receives a voltage CNT_RST. Output OUT delivers an output signal CNT LOW indicating the value of counter 403.

Logic gate 404 is an “AND”-type logic gate comprising an inverting input receiving voltage VBAT LEVEL and a non-inverting input receiving voltage CNT_EN. Logic gate 404 outputs voltage LEVEL_EN. Logic gate 404 aims at inverting voltage VBAT LEVEL and at transmitting it to counter 403 only if the latter is enabled by voltage CNT_EN.

Logic gate 405 is an “AND”-type gate comprising an input receiving signal CNT LOW and an input receiving a signal CNT_LIM representing the limiting value of the counter. Logic gate 405 outputs a signal LOW_IRQ indicating whether the value of the counter symbolized by signal CNT LOW has reached or not the limiting value CNT_LIM as previously defined. Logic gate 405 aims at verifying whether the value of the counter is equal or not to the limiting value.

Circuit 400 further optionally comprises a circuit 406 (LIM) for generating signal CNT_LIM symbolizing the limiting value of counter 403. Circuit 406 may be a configurable signal source driven by a control unit of device D. According to a variant, circuit 406 may be external to circuit 400, and/or external to device D.

Circuit 400 further comprises a rising edge detector 407 receiving as an input voltage VBAT LEVEL and outputting a signal DET HIGH. Detector 407 is of the type of the detector 302 described in relation with FIG. 3. Detector 407 is configured to indicating to device D that voltage VBAT is greater than threshold voltage V_TH by detecting a rising edge of voltage VBAT LEVEL. In other words, each time voltage VBAT LEVEL indicates that voltage VBAT is greater than threshold voltage V_TH, signal DET HIGH indicates it, for example, by switching to a high level.

Circuit 400 further comprises a logic “AND”-type gate 408 comprising an input receiving signal DET HIGH, and an input receiving voltage CNT_EN. Logic gate 408 outputs voltage HIGH_IRQ. Logic gate 408 aims at only filtering the output of detector 407 when counter 403 is disabled.

Circuit 400 further comprise a circuit 409 for resetting counter 403 taking into account the information of signals DET HIGH and LOW_IRQ to obtain voltage CNT_RST. According to the example of FIG. 4, reset circuit 409 is an “OR”-type logic gate receiving as an input signals DET HIGH and LOW_IRQ.

Circuit 400 further comprises a circuit 410 configured to enable and to disable the interruptions obtained from a voltage drop or from a voltage rise. In FIG. 4, circuit 410 comprises an “AND”-type logic gate 410-1 and an “AND”-type gate 410-2.

Gate 401-1 is configured to enable and disable interruptions obtained by a voltage rise. For this purpose, gate 410-1 receives as an input signal HIGH_IRQ and an enable signal HIGH_IRQ EN and outputs a signal HIGH_IRQ_2.

Gate 410-2 is configured to enable and disable interruptions obtained by a voltage drop. For this purpose, gate 410-2 receives as an input signal LOW_IRQ and an enable signal LOW_IRQ EN and outputs a signal LOW_IRQ_2.

Eventually, circuit 400 further comprises an interruption generation circuit 411. In FIG. 4, circuit 411 is an “OR” logic gate receiving as an input signals HIGH_IRQ_2 and LOW_IRQ_2 and outputting a signal IRQ.

FIG. 5 shows timing diagrams of voltages and signals of the monitoring circuit 400 described in relation with FIG. 4 enabling to describe the operation of this circuit 400.

FIG. 5 comprises, in particular: a timing diagram of voltage VBAT; a timing diagram of voltage VBAT LEVEL; a temporal representation of the operating mode CNT_STATE of counter 403; a timing diagram of signal LOW_IRQ EN; a timing diagram of signal HIGH_IRQ EN; a timing diagram of interruption signal IRQ; and a temporal representation of the operating mode DEVICE_STATE of device D.

At an initial time t0, the previously-mentioned signals, counter 403, and device D are in the following states.

The voltage VBAT of the battery of device D is greater than threshold voltage V_TH, having its level shown by a dotted line.

Voltage VBAT LEVEL representing the result of the comparison between voltage VBAT and threshold voltage V_TH is in a high state indicating that voltage VBAT is greater than threshold voltage V_TH.

Counter 403 has been reset and is thus in an initial state noted “0” (0). Counter 403 is not counting.

Signal LOW_IRQ EN is in a state indicating that interruptions due to a voltage VBAT smaller than threshold voltage V_TH for an extended duration are authorized. According to an example, signal LOW_IRQ EN is in a high state.

Signal HIGH_IRQ EN is in a state indicating that interruptions due to a voltage VBAT greater than threshold voltage V_TH for an extended duration are not authorized. According to an example, signal LOW_IRQ EN is in a low state.

Interruption signal IRQ is in a state indicating that no interruption is, at time to, transmitted. According to an example, signal IRQ is in a low state.

Device D is in a “full power” operating mode (HIGH PERF) where it does not particularly decrease its energy consumption.

At a time t1, subsequent to time t0, voltage VBAT decreases and becomes lower than threshold voltage V_TH. Voltage VBAT LEVEL then exhibits a falling edge, which enables to start counter 403. Counter 403 is then in a counting state (1, 2, 3, . . . ).

At a time t2, subsequent to time t1, voltage VBAT increases and becomes greater than threshold voltage V_TH. Voltage VBAT LEVEL then exhibits a rising edge. Counter 403 stops counting and switches back to its initial value (0). The duration between time t1 and time t2 is not long enough and counter 403 has not had time to end its counting, in other words, the value of counter 403 has remained lower than limiting value CNT_LIM.

Further, at time t2, device D being in a “full power” operating state, during which it does not attempt to decrease its energy consumption, interruptions due to a voltage VBAT greater than threshold voltage V_TH are not authorized. In other words, signal HIGH_IRQ EN is in a low state. Thus, no interruption IRQ is generated.

Until a time t5, subsequent to time t2, voltage VBAT oscillates between a value greater than threshold voltage V_TH and a value smaller than threshold voltage V_TH, and this, without for the counter value to succeed in reaching limiting value CNT_LIM. More particularly: at a time t3, subsequent to time t2, voltage VBAT becomes smaller than the threshold voltage; at a time t4, subsequent to time t3, voltage VBAT becomes greater than threshold voltage V_TH; and at time t5, subsequent to time t4, voltage VBAT becomes smaller than threshold voltage V_TH.

At a time t6, subsequent to time t5, the incrementing value of counter 403 reaches limiting value CNT_LIM. Signal LOW_IRQ EN being in a high state, an interruption may be sent, signal IRQ thus briefly transits to a high state. On reception of the interruption, device D may switch to a “low consumption” or “low power” mode, where it decreases its energy consumption as previously described. Further, counter 403 is reset to its initial value.

Further, by switching to a “low consumption” mode, device D modifies the type of interruption that it can receive. Indeed, only an interruption indicating that voltage VBAT is greater than threshold voltage V_TH is interesting. Thus, signal LOW_IRQ EN switches to a low state and signal HIGH_IRQ EN switches to a high state.

At a time t7, subsequent to time t6, voltage VBAT becomes greater than threshold voltage V_TH. Signal HIGH_IRQ EN being in a high state, an interruption may be sent, signal IRQ thus briefly transits to a high state. On reception of the interruption, device D may switch back to a “full power” mode, where it no longer decreases its energy consumption.

Further, by switching to a “full power” mode, device D modifies the type of interruption that it can receive. Thus, signal LOW_IRQ EN switches to a high state and signal HIGH_IRQ EN switches to a low state.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove.

1. A circuit for monitoring a first voltage delivered by a battery, comprising:
a comparator configured to compare the first voltage with a second voltage and generate a first logic signal having a logic state dependent on the comparison;
an edge detector configured to receive the first logic signal and assert a second logic signal in response to detection of an edge of the first signal indicating that the first voltage has exceeded the second voltage;
a counter configured to start counting each time the logic state of the first logic signal indicates that the first voltage is less than the second voltage and generate a third logic signal having a logic state dependent on whether a value of the counter exceeds a count limit; and
a combinational logic circuit configured to logically combine the second logic signal and the third logic signal to generate a fourth logic signal;
wherein logic state transitions of the fourth logic signal control modification of an operating mode of an electronic device comprising said battery between a high performance operating mode and a low performance operating mode.

2. The circuit of claim 1, wherein said combinational logic circuit comprises:
a first logic-AND gate having a first input configured to receive the second logic signal, a second input configured to receive a first enable signal asserted logic high when the electronic device is in the low performance operating mode, and an output configured to generate a fifth logic signal;
a second logic-AND gate having a first input configured to receive the third logic signal, a second input configured to receive a second enable signal asserted logic high when the electronic device is in the high performance operating mode, and an output configured to generate a sixth logic signal; and
a first logic-OR gate having a first input configured to receive the fifth logic signal, a second input configured to receive the sixth logic signal, and an output configured to generate said fourth logic signal.

3. The circuit of claim 2, wherein, responsive to said first enable signal being asserted logic high and assertion of the second logic signal, said fourth logic signal pulses to indicate to said electronic device comprising said battery to switch from the low performance operating mode to the high performance operating mode.

4. The circuit of claim 2, wherein, responsive to said second enable signal being asserted logic high and assertion of the third logic signal, said fourth logic signal pulses to indicate to said electronic device comprising said battery to switch from the high performance operating mode to the low performance operating mode.

5. The circuit of claim 2, wherein said combinational logic circuit further comprises a second logic-OR gate having a first input configured to receive the second logic signal and a second input configured to receive the third logic signal, and an output configured to generate a counter reset signal applied to control reset of the counter.

6. An electronic device, comprising: a battery and the monitoring circuit according to claim 1.

7. The electronic device of claim 6, further comprising a near-field communication circuit.

8. A circuit for monitoring a first voltage delivered by a battery, comprising:
a comparator configured to compare the first voltage with a second voltage;
a counter configured to start counting each time the comparator indicates that the first voltage is smaller than the second voltage; and
a logic circuit configured to generate an interruption signal;
wherein said interruption signal is generated when a value of the counter during said counting exceeds a limiting value; and
wherein said interruption signal is generated when the comparator indicates that the first voltage is greater than the second voltage.

9. The circuit according to claim 8, wherein the interruption signal is configured to modify an operating mode of an electronic device comprising said battery.

10. The circuit according to claim 9, wherein when the interruption signal is generated because said value of the counter exceeds the limiting value then said electronic device switches to a low-consumption mode.

11. The circuit according to claim 10, wherein when the electronic device is in a low-consumption mode, then generating the interruption signal gas a result of the value of said counter is greater than said limiting value is disabled.

12. The circuit according to claim 11, wherein modifying the operating mode comprises decreasing a clock frequency for a processor during the low-consumption mode.

13. The circuit according to claim 8, wherein when the interruption signal is generated because said first voltage is greater than the second voltage then said electronic device switches to a full power mode.

14. The circuit according to claim 13, wherein when the device is in a full power mode, then generation of the interruption signal because said first voltage is greater than said second voltage is disabled.

15. The circuit according to claim 8, wherein the counter is configured to be reset each time the first voltage is greater than the second voltage.

16. The circuit according to claim 8, wherein the counter is configured to be reset each time said value of the counter is greater than said limiting value.

17. The circuit according to claim 8, wherein the second voltage is configurable.

18. The circuit according to claim 8, wherein the limiting value is configurable.

19. An electronic device, comprising a battery and said monitoring circuit according to claim 8.

20. The electronic device according to claim 19, further comprising a near-field communication circuit.
